(19) United States
(12) Patent Application Publication
(10) Pub. No.: US 2024/0276677 A1
(43) Pub. Date: Aug. 15, 2024

(54) THERMAL DIFFUSION DEVICE

(71) Applicant: Murata Manufacturing Co., Ltd., Nagaokakyo-shi (JP)

(72) Inventor: Tatsuhiro NUMOTO, Nagaokakyo-shi, Kyoto-fu (JP)

(21) Appl. No.: 18/641,700

(22) Filed: Apr. 22, 2024

Related U.S. Application Data
(63) Continuation of application No. PCT/JP2022/041867, filed on Nov. 10, 2022.

(30) Foreign Application Priority Data
Nov. 15, 2021 (JP) 2021-185679

(51) Int. Cl. H05K 7/20

(52) U.S. Cl. CPC H05K 7/20336

(57) ABSTRACT

A thermal diffusion device that includes: a housing having a first inner wall surface and a second inner wall surface facing each other in a thickness direction and defining an internal space of the housing; a working medium enclosed in the internal space of the housing; and a wick having a sheet shape and disposed in the internal space of the housing, wherein the wick has at least one bent portion protruding from the first inner wall surface toward the second inner wall surface, and wherein a space defined by the at least one bent portion of the wick and the first inner wall surface forms a liquid channel for the working medium.

### CROSS REFERENCE TO RELATED APPLICATIONS

The present application is a continuation of International application No. PCT/JP2022/041867, filed Nov. 10, 2022, which claims priority to Japanese Patent Application No. 2021-185679, filed Nov. 15, 2021, the entire contents of each of which are incorporated herein by reference.

### TECHNICAL FIELD

The present description relates to a thermal diffusion device.

### BACKGROUND ART

With recent high integration and enhanced performance, devices have increased heat generation. In addition, as products continue to decrease in size, the density of heat generation increases. Thus, heat dissipation measures play a significant role. This situation is particularly noticeable in the field of mobile terminals, including smartphones and tablets. For example, a graphite sheet is usually used as a heat management member, but its heat capacity is insufficient. Thus, various other heat management members are studied for use. Among these, the use of a vapor chamber, which is a plane heat pipe, as a thermal diffusion device capable of highly effectively dissipating heat has been studied.

A vapor chamber has a structure having a housing enclosing a working medium (also referred to as a working fluid) and a wick that transports the working medium with capillary attraction. The working medium absorbs heat from a heater element such as an electronic component in an evaporation portion that absorbs heat from the heater element, evaporates in the vapor chamber, and is then cooled while moving through the vapor chamber to return into a liquid phase. The working medium that has returned into a liquid phase moves to the evaporation portion located nearer the heater element again by the capillary attraction of the wick to cool the heater element. With repetition of this cycle, the vapor chamber can independently operate without external power, and two-dimensionally dissipate heat at high speeds using evaporative latent heat and condensable latent heat of the working medium.

To achieve the thickness reduction of a mobile terminal such as a smartphone or a tablet, thickness reduction of the vapor chamber is also involved. The vapor chamber with a reduced thickness may fail to ensure mechanical strength and heat transport efficiency.

To retain the internal space of a housing defining the vapor chamber, Patent Document 1 describes a support member disposed in the housing.

Patent Document 1 discloses a vapor chamber that includes a container having a hollow defined by a first plate body to which a heat generator is thermally connected and a second plate body facing the first plate body, a working fluid enclosed in the hollow, and a wick structure accommodated in the hollow and separate from the container. The container has a support member that is formed by forming a recess in an outer surface of the second plate body to protrude toward the first plate body from an inner surface of the second plate body. An angle between the inner surface of the second plate body and the support member at a base of the support member from which the second plate body rises is an obtuse angle.

Patent Document 1: Japanese Unexamined Patent Application Publication No. 2021-76355

### SUMMARY OF THE DESCRIPTION

In the vapor chamber described in Patent Document 1, the total of the height of the support member and the thickness of the wick structure is equivalent to the thickness of the internal space. Thus, adjusting the height of the support member and the thickness of the wick structure enables thickness reduction of the vapor chamber. However, to enhance the heat dissipation efficiency of the vapor chamber, the adjustment has room for improvement.

Not only the vapor chamber, but also a thermal diffusion device capable of dissipating heat with the same structure as the vapor chamber has the same issue as described above.

The present description is made to address the above issue, and aims to provide a thermal diffusion device with high heat dissipation efficiency. The present description further aims to provide an electronic device including the above thermal diffusion device.

A thermal diffusion device of the present description includes: a housing having a first inner wall surface and a second inner wall surface facing each other in a thickness direction and defining an internal space of the housing; a working medium enclosed in the internal space of the housing; and a wick having a sheet shape and disposed in the internal space of the housing, wherein the wick has at least one bent portion protruding from the first inner wall surface toward the second inner wall surface, and wherein a space defined by the at least one bent portion of the wick and the first inner wall surface forms a liquid channel for the working medium.

An electronic device according to the present description includes a thermal diffusion device according to the present description.

The present description can provide a thermal diffusion device with high heat dissipation efficiency. The present description can further provide an electronic device including the thermal diffusion device.

### BRIEF DESCRIPTION OF THE DRAWINGS

FIG. 1 is a schematic perspective view of an example of a thermal diffusion device according to a first embodiment of the present description.

FIG. 2 is a schematic plan view of an example of an internal structure of the thermal diffusion device according to the first embodiment of the present description.

FIG. 3 is an example of a cross-sectional view of the thermal diffusion device taken along line A-A in FIG. 2.

FIG. 4 is another example of a cross-sectional view of the thermal diffusion device taken along line A-A in FIG. 2.

FIG. 5 is a schematic plan view of an example of an internal structure of a thermal diffusion device according to a second embodiment of the present description.

FIG. 6 is an example of a cross-sectional view of the thermal diffusion device taken along line A-A in FIG. 5.

FIG. 7 is a schematic plan view of an example of an internal structure of a thermal diffusion device according to a third embodiment of the present description.

FIG. 8 is an example of a cross-sectional view of a thermal diffusion device taken along line A-A in FIG. 7.

### DETAILED DESCRIPTION OF THE PREFERRED EMBODIMENTS

A thermal diffusion device of the present description is described below.

However, the present invention is not limited to the embodiments below, and may be applicable by being changed as appropriate within a scope not changing the scope of the present invention. A combination of two or more preferable structures of the present description described below is also included in the scope of the present description.

In a thermal diffusion device of the present description, a wick with a sheet shape is disposed in the internal space of the housing. Thus, unlike a thermal diffusion device including a wick extending linearly, the thermal diffusion device of the present description has no limitation on the size of a vapor-liquid replacement surface.

The wick with a sheet shape has a bent portion protruding from the first inner wall surface of the housing toward the second inner wall surface, and a liquid channel for the working medium in a space defined by the bent portion of the wick and the first inner wall surface. Thus, in addition to capillary attraction caused by the wick located around the liquid channel, reduction of the resistance of the liquid flowing through the liquid channel allows the working medium to smoothly move through the liquid channel. This structure can thus enhance transmission rate compared to a structure merely including a wick.

Thus, the thermal diffusion device according to the present description has increased maximum heat capacity, and enhanced heat dissipation efficiency.

The embodiments described below are mere examples, and components in different embodiments may naturally be partially replaced with one another or combined with one another. In the second embodiment and the subsequent embodiments, components or structures the same as those in the first embodiment are not described and only the difference therebetween are described. Particularly, the same effects from the same components are not described in all the embodiments.

In the following description, each of thermal diffusion devices according to embodiments is simply referred to as “a thermal diffusion device according to the present description” unless particularly distinguished between the embodiments.

Hereafter, for example, a vapor chamber is described as a thermal diffusion device according to an embodiment of the present description. The thermal diffusion device according to the present description is applicable to a thermal diffusion device such as a heat pipe.

The drawings described below are schematic, and may differ from actual products in terms of dimensions or reduced scale in the aspect ratio.

Herein, terms describing the relationship between components (for example, vertical, parallel, and perpendicular) and terms describing the shapes of components do not express the meanings in a strict sense but include the substantially equivalent ranges of each term, such as the differences within about several percents.

### First Embodiment

In a thermal diffusion device according to a first embodiment of the present description, two or more bent portions of a wick are arranged in parallel to one another. These bent portions are disposed to converge on an evaporation portion.

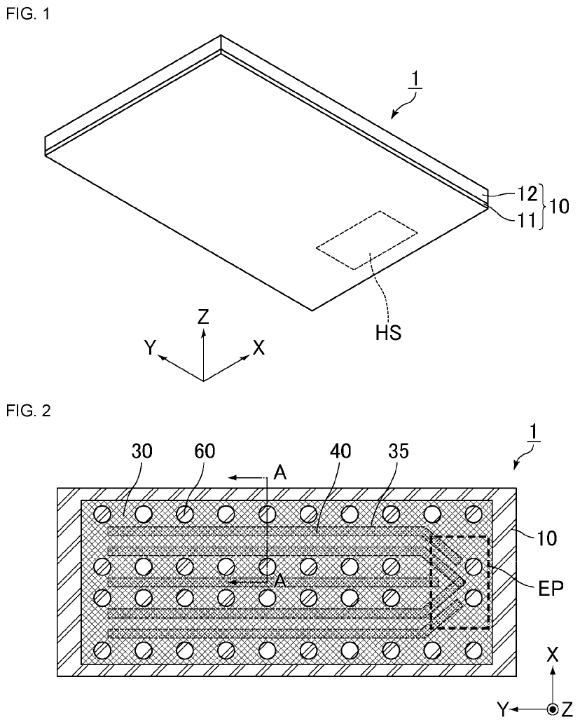

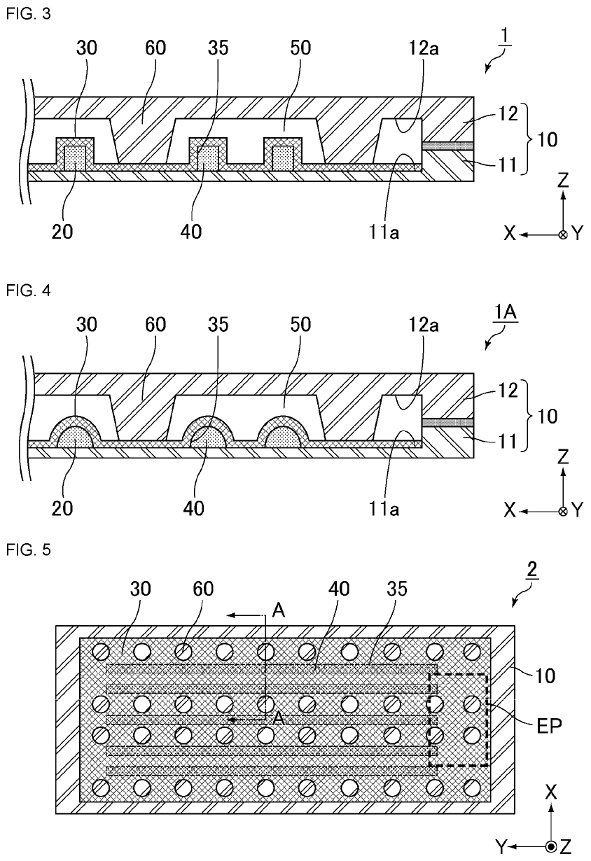

FIG. 1 is a schematic perspective view of an example of a thermal diffusion device according to a first embodiment of the present description. FIG. 2 is a schematic plan view of an example of an internal structure of the thermal diffusion device according to the first embodiment of the present description. FIG. 3 is an example of a cross-sectional view of the thermal diffusion device taken along line A-A in FIG. 2.

A vapor chamber (thermal diffusion device) 1 illustrated in FIG. 1 includes a hollow housing 10 that is hermetically sealed. As illustrated in FIG. 3, the housing 10 includes a first inner wall surface 11a and a second inner wall surface 12a facing in a thickness direction Z. The vapor chamber 1 further includes a working medium 20 enclosed in the internal space of the housing 10, and a wick 30 disposed in the internal space of the housing 10.

As illustrated in FIG. 2, an evaporation portion EP that evaporates the enclosed working medium 20 (refer to FIG. 3) is installed at the housing 10. As illustrated in FIG. 1, a heat source HS serving as a heater element is disposed on an outer wall surface of the housing 10. Examples of the heat source H includes an electronic component of an electronic device such as a central processing unit (CPU). In the internal space of the housing 10, a portion located near the heat source HS and heated by the heat source HS corresponds to the evaporation portion EP.

Preferably, the vapor chamber 1 is entirely plane. More specifically, the housing 10 is preferably entirely plane. In this case, “plane” includes a plate shape and a sheet shape, or indicates a shape having a dimension in a width direction X (referred to as a width below) and a dimension in a length direction Y (referred to as a length below) relatively greater than a dimension in a thickness direction Z (referred to as a thickness or a height below), for example, a shape where the width and the length are equal to or greater than ten times the thickness, or more preferably, hundred times the thickness.

The size of the vapor chamber 1, that is, the size of the housing 10 is not limited in particular. The width and the length of the vapor chamber 1 may be set as appropriate for the purpose of use. The width and the length of the vapor chamber 1 are, for example, greater than or equal to 5 mm and smaller than or equal to 500 mm, greater than or equal to 20 mm and smaller than or equal to 300 mm, or greater than or equal to 50 mm and smaller than or equal to 200 mm. The width and the length of the vapor chamber 1 may be the same or different.

Preferably, the housing 10 is formed from a first sheet 11 and a second sheet 12 having outer peripheral portions joined to each other and facing each other.

When the housing 10 is formed from the first sheet 11 and the second sheet 12, the first sheet 11 and the second sheet 12 may be formed from any material having characteristics appropriate for use as a vapor chamber, such as thermal conductivity, strength, softness, and flexibility. Preferably, the material forming the first sheet 11 and the second sheet 12 is metal, such as copper, nickel, aluminum, magnesium, titanium, iron, or an alloy containing any of these metals as a main component. Particularly preferably, the material is copper. The first sheet 11 and the second sheet 12 may be formed from the same material or different materials, but preferably, the same material.

When the housing 10 is formed from the first sheet 11 and the second sheet 12, the first sheet 11 and the second sheet 12 are joined to each other at their outer peripheral portions. The method with which the first sheet 11 and the second sheet 12 are joined is not limited in particular. Examples of the method include laser welding, resistance welding, diffusion bonding, brazing and soldering, tungsten inert-gas welding (TIG welding), ultrasonic bonding, or plastic molding. Preferably, the method may be laser welding, resistance welding, or brazing and soldering.

The thickness of the first sheet 11 and the second sheet 12 is not limited in particular, and is preferably greater than or equal to 10 μm and smaller than or equal to 200 μm, more preferably, greater than or equal to 30 μm and smaller than or equal to 100 μm, or further more preferably, greater than or equal to 40 μm and smaller than or equal to 60 μm. The thickness of the first sheet 11 and the second sheet 12 may be the same or different. The thickness of the first sheet 11 and the second sheet 12 may be uniform throughout, or partially reduced.

The shapes of the first sheet 11 and the second sheet 12 are not limited in particular. For example, the first sheet 11 and the second sheet 12 may have the outer peripheral portions thicker than portions other than the outer peripheral portions.

The thickness of the entire vapor chamber 1 is not limited in particular, but is preferably greater than or equal to 50 μm and smaller than or equal to 500 μm.

The shape of the housing 10 in a plan viewed in the thickness direction Z is not limited in particular. Examples of the shape include, a polygon such as a triangle or a rectangle, a circle, an ellipse, and a shape combining any of these. Alternatively, the shape of the housing 10 in a plan may be a letter L shape, a letter C shape (or an angular C shape), or a step shape. The housing 10 may have a through-hole. The housing 10 may have a shape in a plan that fits the purpose of a vapor chamber, the shape of an insertable portion of the vapor chamber, or another component located near the housing 10.

The working medium 20 is not limited in particular and may be any medium that can cause vapor-liquid phase changes under the environments in the housing 10. The working medium 20 may be, for example, water, alcohol, or alternative chlorofluorocarbon. For example, the working medium 20 is an aqueous compound, and preferably, water.

As illustrated in FIG. 2 and FIG. 3, the wick 30 has a sheet shape as a whole. The sheet shape indicates a shape having a width and a length relatively greater than the thickness, for example, a width and a length greater than or equal to ten times the thickness, or more preferably, greater than or equal to hundred times the thickness.

The wick 30 has a capillary structure that allows the working medium 20 to move through capillary attraction. The capillary structure of the wick 30 may be a known structure used in an existing vapor chamber. Examples of the capillary structure includes a fine structure including unevenness such as pores, grooves, and projections, such as a vesicular structure, a fibrous structure, a groove structure, and a network structure.

The material of the wick 30 is not limited in particular, and includes, for example, a metal porous film formed through etching or metal processing, a mesh, a nonwoven fabric, a sintered body, and a porous body. The mesh serving as the material of the wick 30 may be formed from, for example, a metal mesh, a resin mesh or a metal or resin mesh having surfaces coated. Preferably, the mesh is formed from a copper mesh, a stainless-steel (SUS) mesh, or a polyester mesh. A sintered body serving as the material of the wick 30 may be formed from, for example, a metal porous sintered body, or a ceramic porous sintered body, or preferably, a copper or nickel porous sintered body. A porous body serving as the material of the wick 30 may be formed from, for example, a metal porous body, a ceramic porous body, or a resin porous body.

The thickness of the wick 30 is not limited in particular, but preferably, for example, greater than or equal to 2 μm and smaller than or equal to 200 μm, preferably, greater than or equal to 5 μm and smaller than or equal to 100 μm, or more preferably, greater than or equal to 10 μm and smaller than or equal to 40 μm. The thickness of the wick 30 may partially vary, but is preferably uniform.

Although the size and the shape of the wick 30 are not limited in particular, preferably, for example, the wick 30 is disposed continuously in the internal space of the housing 10. In the example illustrated in FIG. 2 and FIG. 3, the wick 30 is disposed throughout the internal space of the housing 10. However, the wick 30 may be partially present in the internal space of the housing 10. For example, in FIG. 2 and FIG. 3, the wick 30 is in contact with the outer peripheral portion of the internal space of the housing 10, but may be not be in contact with the outer peripheral portion of the internal space of the housing 10.

As illustrated in FIG. 3, the wick 30 is disposed along the first inner wall surface 11a of the housing 10. The wick 30 has bent portions 35 that protrude from the first inner wall surface 11a toward the second inner wall surface 12a. The space defined by the bent portions 35 of the wick 30 and the first inner wall surface 11a forms liquid channels 40 for the working medium 20. A vapor channel 50 for the working medium 20 is formed in a gap in the housing 10 excluding the liquid channels 40.

As illustrated in FIG. 2 and FIG. 3, the bent portions 35 of the wick 30 extend in a longitudinal direction of the housing 10 (length direction Y in FIG. 2 and FIG. 3) when viewed in a plan in the thickness direction Z.

In the example illustrated in FIG. 2 and FIG. 3, the two or more bent portions 35 are arranged in parallel to one another, but one bent portion 35 may be arranged.

When the two or more bent portions 35 are arranged, the bent portions 35 may be arranged to converge on the evaporation portion EP as illustrated in FIG. 2. More specifically, to converge on the evaporation portion EP, at least one bent portion 35 may have at least one bend when viewed in a plan in the thickness direction Z. When the bent portions 35 converge on the evaporation portion EP, the working medium 20 can circulate over short distances.

In a cross-sectional view taken perpendicular to the direction in which the bent portions 35 extend, the width of the bent portions 35 is not limited in particular, but may be, for example, greater than or equal to 10 μm and smaller than or equal to 1000 μm. The width of the bent portions 35 is equivalent to the width of the liquid channels 40. The width of the bent portions 35 may be uniform or nonuniform in the thickness direction Z. When the bent portions 35 have a width that varies in the thickness direction Z, the width at a widest portion is defined as the width of the bent portions 35.

In a cross-sectional view taken perpendicular to the direction in which the bent portions 35 extend, the height of the bent portions 35 is not limited to a particular height, but may be, for example, greater than or equal to 10 μm and smaller than or equal to 100 μm. The height of the bent portions 35 is equivalent to the height of the liquid channels 40. The height of the bent portions 35 may be uniform or nonuniform in the width direction X and the length direction Y. When the height of the bent portions 35 varies in the width direction X and the length direction Y, the height at a highest portion is defined as the height of the bent portions 35.

As illustrated in FIG. 2 and FIG. 3, preferably, support struts 60 in contact with the second inner wall surface 12a are disposed in the internal space of the housing 10. The support struts 60 are disposed in the vapor channel 50. The vapor channel 50 is divided by the support struts 60.

When the support struts 60 are disposed in the internal space of the housing 10, the support struts 60 can support the housing 10. The support struts 60 may support the wick 30 by pressing the wick 30.

When the support struts 60 are disposed in the internal space of the housing 10, the bent portions 35 of the wick 30 are preferably disposed in an area not held between the support struts 60 and the first inner wall surface 11a, as illustrated in FIG. 2 and FIG. 3. In other words, in the thickness direction Z, preferably, the bent portions 35 of the wick 30 are not disposed between the support struts 60 and the first inner wall surface 11a. When the bent portions 35 forming the liquid channels 40 are disposed between adjacent support struts 60, the maximum heat capacity can be increased without increasing the thickness of the entire vapor chamber 1.

When the two or more bent portions 35a are arranged in an area not held between the support struts 60 and the first inner wall surface 11a, the number of bent portions 35 disposed between any two of the support struts 60 may be the same or different.

The support struts 60 may be in contact with the wick 30 or fixed to the wick 30. The support struts 60 fixed to the wick 30 facilitates assembly of the vapor chamber 1. For example, when the wick 30 and the support struts 60 are formed from metal, the wick 30 may be joined to the support struts 60. Although the method for joining the wick 30 and the support struts 60 is not limited in particular, the method may be, for example, diffusion bonding. Instead, the wick 30 may be bonded to the support struts 60 with a silica film.

The support struts 60 may be disposed throughout inside the vapor channels 50, or may be partially present in the vapor channels 50.

Although the material forming the support struts 60 is not limited in particular, examples of the material include resin, metal, ceramics, a mixture of any of these, and a laminated body. The support struts 60 may be integrated with the housing 10, or for example, formed by etching the inner wall surface of the housing 10.

The shape of the support struts 60 is not limited in particular and may be any shape capable of supporting the housing 10 and the wick 30. Examples of the cross-sectional shape of the support struts 60 taken perpendicular to the height direction include a polygon such as a rectangle, a circle, and an ellipse.

The height of the support struts 60 in one vapor chamber may be the same or different.

In a cross section in FIG. 3, the width of the support struts 60 is not limited in particular as long as the support struts 60 with the width exert strength to reduce deformation of the housing 10. The equivalent circle diameter of a cross section at the end portions of the support struts 60 taken perpendicular to the height direction is, for example, greater than or equal to 100 μm and smaller than or equal to 2000 μm, or more preferably, greater than or equal to 300 μm and smaller than or equal to 1000 μm. Increasing the equivalent circle diameter of the support struts 60 can further reduce deformation of the housing 10. In contrast, reducing the equivalent circle diameter of the support struts 60 can ensure a larger space for the vapor of the working medium 20 to move.

The arrangement of the support struts 60 is not limited in particular. Preferably, the support struts 60 are evenly arranged in a predetermined area, or more preferably, evenly arranged throughout, for example, at regular intervals between one another. Evenly arranging the support struts 60 ensures uniform strength throughout the vapor chamber 1.

Each bent portion 35 of the wick 30 forming the corresponding liquid channel 40 has a shape bent from the wick 30. The bent portions 35 of the wick 30 can be formed by, for example, embossing the wick 30. The cross-sectional shape of the bent portions 35 taken perpendicular to the extension direction is not limited in particular. For example, in the vapor chamber 1 illustrated in FIG. 3, the cross-sectional shape of the bent portions 35 taken perpendicular to the extension direction is a quadrilateral such as a rectangle. When the two or more bent portions 35 are arranged, the cross-sectional shape of the bent portions 35 may be the same or different.

FIG. 4 is another example of a cross-sectional view of the thermal diffusion device taken along line A-A in FIG. 2.

In a vapor chamber (thermal diffusion device) 1A illustrated in FIG. 4, the cross section of the bent portions 35 taken perpendicular to the extension direction is semicircular.

As illustrated in FIG. 4, the cross-sectional shape of the bent portions 35 taken perpendicular to the extension direction may be semicircular or semi-elliptic, or polygonal such as triangular. Instead, the cross-sectional shape may be a polygon with rounded corners. When the bent portions 35 have a rounded cross-sectional shape, the resistance of a liquid flowing through the liquid channels 40 can be reduced.

### Second Embodiment

In a thermal diffusion device according to a second embodiment of the present description, the bent portions of the wick extend in only one direction.

In the second embodiment of the present description, a jig used to form the bent portions of the wick and a process of forming the bent portions are further simplified than in the first embodiment of the present description. Thus, the thermal diffusion device can increase the yield.

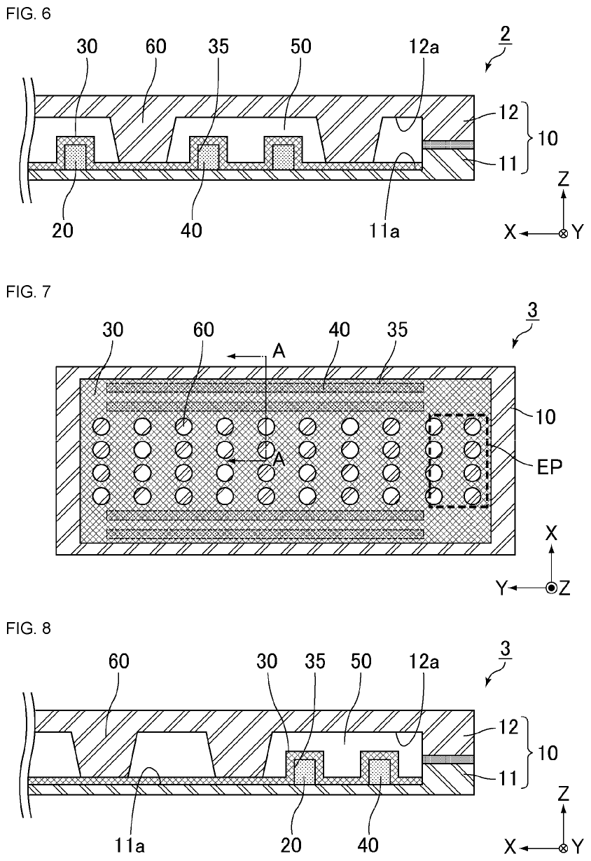

FIG. 5 is a schematic plan view of an example of an internal structure of a thermal diffusion device according to a second embodiment of the present description. FIG. 6 is an example of a cross-sectional view of the thermal diffusion device taken along line A-A in FIG. 5.

In a vapor chamber (thermal diffusion device) 2 illustrated in FIG. 5 and FIG. 6, the bent portions 35 of the wick 30 extend in only one direction instead of being arranged to converge on the evaporation portion EP. Thus, each bent portion 35 has no bend in a plan view viewed in the thickness direction Z. More specifically, the bent portions 35 extend in only the longitudinal direction of the housing 10 (length direction Y in FIG. 5 and FIG. 6) in a plan view viewed in the thickness direction Z.

In the example illustrated in FIG. 5 and FIG. 6, the two or more bent portions 35 are arranged in parallel to one another, but one bent portion 35 may be arranged.

### Third Embodiment

In a thermal diffusion device according to a third embodiment of the present description, the bent portions of the wick are arranged along the outer peripheral portion of the internal space of the housing.

In the third embodiment of the present description, the bent portions of the wick are not arranged throughout the internal space of the housing. Thus, a wide vapor channel is ensured. The internal space of the housing thus has high thermal conductivity at a center portion, and has improved temperature uniformity.

FIG. 7 is a schematic plan view of an example of an internal structure of a thermal diffusion device according to a third embodiment of the present description. FIG. 8 is an example of a cross-sectional view of a thermal diffusion device taken along line A-A in FIG. 7.

In a vapor chamber (thermal diffusion device) 3 illustrated in FIG. 7 and FIG. 8, the bent portions 35 of the wick 30 are arranged along the outer peripheral portion of the internal space of the housing 10. In the example illustrated in FIG. 7 and FIG. 8, two or more bent portions 35 are arranged along the outer peripheral portion of the internal space of the housing 10 without being arranged at a center portion of the internal space of the housing 10.

In the example illustrated in FIG. 7 and FIG. 8, the two or more bent portions 35 are arranged in parallel to one another, but one bent portion 35 may be arranged. In either case, the bent portion or portions 35 is/are arranged only at the outer peripheral portion of the internal space of the housing 10 without being arranged at the center portion of the internal space of the housing 10.

### Other Embodiments

A thermal diffusion device according to the present description is not limited to those in the above embodiments, and may be modified or applied to various other purposes within the scope of the present description in terms of, for example, components of the thermal diffusion device or manufacturing conditions of the thermal diffusion device.

In a thermal diffusion device according to the present description, a housing may include one or more evaporation portions. More specifically, one or more heat sources may be disposed on the outer wall surface of the housing. The number of evaporation portions and the number of heat sources are not limited in particular.

In a thermal diffusion device according to the present description, when the housing is formed from a first sheet and a second sheet, the first sheet and the second sheet may overlap one another while having their end portions aligned or misaligned.

In a thermal diffusion device according to the present description, when the housing is formed from a first sheet and a second sheet, the material of the first sheet and the material of the second sheet may be different. For example, when the material with high strength is used for the first sheet, the stress on the housing can be dispersed. When the first sheet and the second sheets are formed from different materials, one of the sheets has a first function, and the other sheet has a second function. Although not limited in particular, examples of the above functions include a thermal conduction function and an electromagnetic shielding function.

A thermal diffusion device according to the present description can be installed in an electronic device for the purpose of heat dissipation. Thus, an electronic device including a thermal diffusion device according to the present description is also regarded as within the scope of the present description. Examples of an electronic device of the present description include a smartphone, a tablet terminal, a laptop computer, a video game machine, and a wearable device. As described above, a thermal diffusion device according to the present description can independently operate without external power, and two-dimensionally dissipate heat at high speeds using evaporative latent heat and condensable latent heat of the working medium. Thus, the electronic device including the thermal diffusion device according to the present description can effectively dissipate heat within a limited space inside the electronic device.

A thermal diffusion device according to the present description is usable for a wide range of applications in the field of, for example, a mobile information terminal. For example, the thermal diffusion device is usable to lower the temperature of a heat source of, for example, a CPU to extend the time for use of the electronic device, and applicable to, for example, a smartphone, a tablet terminal, or a laptop computer.

### REFERENCE SIGNS LIST

1, 1A, 2, 3 vapor chamber (thermal diffusion device)

10 housing

11 first sheet

11a first inner wall surface

12 second sheet

12a second inner wall surface

20 working medium

30 wick

35 bent portion

40 liquid channel

50 vapor channel

60 support strut

EP evaporation portion

HS heat source

X width direction

Y length direction

Z thickness direction

1. A thermal diffusion device, comprising:
a housing having a first inner wall surface and a second inner wall surface facing each other in a thickness direction and defining an internal space of the housing;
a working medium enclosed in the internal space of the housing; and
a wick having a sheet shape and disposed in the internal space of the housing,
wherein the wick has at least one bent portion protruding from the first inner wall surface toward the second inner wall surface, and
wherein a space defined by the at least one bent portion of the wick and the first inner wall surface forms a liquid channel for the working medium.

2. The thermal diffusion device according to claim 1, further comprising:
a support strut disposed in the internal space of the housing and in contact with the second inner wall surface,
wherein the at least one bent portion of the wick is disposed in an area that is not between the support strut and the first inner wall surface.

3. The thermal diffusion device according to claim 2, wherein the at least one bent portion of the wick extends in a longitudinal direction of the housing.

4. The thermal diffusion device according to claim 3, wherein the at least one bent portion of the wick extends in only one direction.

5. The thermal diffusion device according to claim 3, wherein the wick includes two or more bent portions arranged in parallel to one another.

6. The thermal diffusion device according to claim 3, wherein the at least one bent portion of the wick is disposed along an outer peripheral portion of the internal space of the housing.

7. The thermal diffusion device according to claim 1, wherein the at least one bent portion of the wick extends in a longitudinal direction of the housing.

8. The thermal diffusion device according to claim 7, wherein the at least one bent portion of the wick extends in only one direction.

9. The thermal diffusion device according to claim 7, wherein the wick includes two or more bent portions arranged in parallel to one another.

10. The thermal diffusion device according to claim 9, wherein the two or more bent portions of the wick are disposed along an outer peripheral portion of the internal space of the housing.

11. The thermal diffusion device according to claim 1, wherein the at least one bent portion of the wick is disposed along an outer peripheral portion of the internal space of the housing.

12. The thermal diffusion device according to claim 9, wherein the two or more bent portions are arranged to converge on an evaporation portion of the thermal diffusion device.

13. The thermal diffusion device according to claim 7, wherein, in a cross-sectional view perpendicular to the longitudinal direction, a width of the at least one bent portion is greater than or equal to 10 μm and smaller than or equal to 1000 μm.

14. The thermal diffusion device according to claim 7, wherein, in a cross-sectional view perpendicular to the longitudinal direction, a height of the at least one bent portion is greater than or equal to 10 μm and smaller than or equal to 1000 μm.

15. The thermal diffusion device according to claim 1, further comprising:
a plurality of support struts disposed in the internal space of the housing and in contact with the second inner wall surface,
wherein the wick includes two or more bent portions arranged in parallel to one another and extending in a longitudinal direction of the housing, and
wherein the two or more bent portions of the wick are disposed between adjacent support struts of the plurality of support struts.

16. The thermal diffusion device according to claim 7, wherein a cross-sectional shape of the at least one bent portion of the wick perpendicular to the longitudinal direction is a quadrilateral.

17. The thermal diffusion device according to claim 7, wherein a cross-sectional shape of the at least one bent portion of the wick perpendicular to the longitudinal direction is semicircular.

18. An electronic device, comprising:
the thermal diffusion device according to claim 1.
